(19) United States
(12) Patent Application Publication
(10) Pub. No.: US 2026/0362739 A1
(43) Pub. Date: Nov. 12, 2026

(54) FIELD EFFECT TRANSISTOR HAVING A GATE OXIDE WITH A LOW DIELECTRIC CONSTANT

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/562,341

(22) Filed: Mar. 10, 2026

Related U.S. Application Data
(60) Provisional application No. 63/773,269, filed on Mar. 17, 2025.

(51) Int. Cl. H10D 30/66; H10D 30/01; H10D 62/10; H10D 64/27; H10D 64/68

(52) U.S. Cl. CPC H10D 30/66; H10D 30/0291; H10D 62/124; H10D 64/516; H10D 64/518; H10D 64/685; H10D 64/691; H10D 64/693

(57) ABSTRACT

A field effect transistor comprises a volume of semiconductor material, a drain, a source, a drift region, a gate, and a gate oxide. The gate oxide includes a thin oxide portion and a thick oxide portion that is relatively thicker than the thin oxide portion. The source is positioned at a second end of the volume of semiconductor material. The drain is spaced from the source. The drift region is positioned between the source and the drain. The gate is positioned at the second end of the structure. The thick gate oxide is positioned between the gate and the drift region. The thin oxide portion is located between the thick oxide portion and the drift region and/or between the gate and the source. The thick oxide portion is formed from a material having a dielectric constant of less than or approximately equal to four (4).

### CROSS-REFERENCE TO RELATED APPLICATIONS

The current patent application is a non-provisional utility patent application which claims priority benefit of earlier-filed U.S. Provisional Application Ser. No. 63/773,269; titled “IMPROVED FIELD EFFECT TRANSISTOR HAVING A GATE OXIDE WITH A LOW DIELECTRIC CONSTANT”; and filed Mar. 17, 2025. The Provisional Application is hereby incorporated by reference, in its entirety, into the current patent application.

### FIELD

Various examples of the current technology relate to improved field effect transistors that include a gate oxide having a low dielectric constant.

### BACKGROUND

A metal oxide semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

The background discussion is intended to provide information related to the present technology which is not necessarily prior art.

### SUMMARY

Various examples of the current technology address one or more of the above-mentioned problems or other problems experienced by FETs and, more particularly, MOSFETs. The examples provide a field effect transistor (FET) configured to switch on and off at a higher frequency. The switching frequency of the FET varies, at least in part, according to a capacitance between a gate and a drain of the FET, wherein the capacitance is determined, at least in part, by a dielectric constant of a gate oxide material. The FET achieves higher switching frequencies by having the gate oxide formed from material with a lower dielectric constant (relative to commonly used oxides, such as silicon dioxide, aluminum dioxide, hafnium dioxide, silicon nitride, and combinations thereof), thereby reducing the capacitance between the gate and the drain and allowing for higher switching frequencies.

An example of the FET comprises a volume of semiconductor material, a source, a drain, a drift region, a gate, and a gate oxide. The volume of semiconductor material includes vertically spaced first and second ends. The source is positioned adjacent the second end of the volume of semiconductor material. The drain is spaced apart from the source. The drift region is defined by the volume of semiconductor material positioned between the source and the drain. The gate is positioned adjacent the second end of the volume of semiconductor material. The gate oxide includes a thin oxide portion and a thick oxide portion that is relatively thicker than the thin oxide portion. The thin oxide portion is located between the gate and the source, and the thick oxide portion is located between the gate and the drift region. The thick oxide portion is formed of a material having a dielectric constant of less than or approximately equal to four (4).

Another example of the FET comprises a volume of semiconductor material, a source, a drain, a drift region, a gate, and a gate oxide. The volume of semiconductor material includes vertically spaced first and second ends. The source is positioned adjacent the second end of the volume of semiconductor material. The drain is spaced apart from the source. The drift region is defined by the volume of semiconductor material positioned between the source and the drain. The gate is positioned adjacent the second end of the volume of semiconductor material. The gate oxide includes a thin oxide portion and a thick oxide portion that is relatively thicker than the thin oxide portion. The thick oxide portion is located between the gate and the drift region, and the thick oxide portion is formed of a material having a dielectric constant of less than or approximately equal to four (4). The thin oxide portion includes a central section located between the thick oxide portion and the drift region.

Another example of the current technology provides a method of fabricating a field effect transistor (FET). The method comprises providing a volume of semiconductor material to present vertically spaced first and second ends; forming a source adjacent the second end of the volume of semiconductor material; forming a drain spaced from the source, such that a drift region defined by the volume of semiconductor material is positioned between the source and the drain; forming a gate oxide adjacent the second end of the volume of semiconductor material to include a thin oxide portion and a thick oxide portion that is relatively thicker than the thin oxide portion; and forming a gate adjacent the second end of the volume of semiconductor material. The operation of forming the gate oxide includes positioning the thin oxide portion between the gate and the source. The operation of forming the gate oxide includes positioning the thick oxide portion between the gate and the drift region, with the thick oxide portion being formed of a material having a dielectric constant of less than or approximately equal to four (4).

The preceding examples may include any one or more of the following features.

The thick oxide portion may present horizontally opposite first and second margins. The source may include horizontally spaced first and second source portions. The first source portion may be adjacent the first margin of the thick oxide portion, and the second source portion may be adjacent the second margin of the thick oxide portion. The thin oxide portion may include horizontally spaced first and second sections. The first section of the thin oxide portion may be located between the gate and the first source portion, and the second section of the thin oxide portion being located between the gate and the second source portion.

The well may be positioned adjacent the second end of the volume of semiconductor material. The well may include horizontally spaced first and second well portions that define therebetween a JFET neck region of the drift region. The first well portion may be located between the first source portion and the JFET neck region, and the second well portion may be located between the second source portion and the JFET neck region. The first section of the thin oxide portion may be located between the gate and the first well portion, and the second section of the thin oxide portion may be located between the gate and the second well portion. The thick gate oxide portion may extend across at least the JFET neck region.

The thin oxide portion may include a third central section located between the first and second sections of the thin oxide portion. The central section of the thin oxide portion may be located between the thick oxide portion and the JFET neck region.

Each of the first and second well portions may present an innermost margin located at the JFET neck region. The first margin of the thick oxide portion may be adjacent the innermost margin of the first well portion, and the second margin of the thick oxide portion may be adjacent the innermost margin of the second well portion. The central section of the thin oxide portion may extend between the innermost margins of the first and second well portions.

The first well portion may in part underlie the first source portion, and the second well portion may in part underlie the second source portion.

The second end of the volume of semiconductor material may be planar. The source, well, gate, and gate oxide being located at the second end of the volume of semiconductor material, such that the FET is a planar MOSFET.

The well may be positioned adjacent the second end of the volume of semiconductor material. The well may include horizontally spaced first and second well portions that define therebetween a JFET neck region of the drift region. The thick gate oxide portion may extend across at least the JFET neck region.

The thin gate oxide portion may include material selected from the group consisting of silicon dioxide, aluminum dioxide, hafnium dioxide, silicon nitride, and combinations thereof.

The thick gate oxide portion may include material selected from the group consisting of porous silicon dioxide, fluorine-doped silicon oxide, carbon-doped silicon oxide, organosilicate glass, silsesquioxane, and combinations thereof.

The thick oxide portion may present horizontally opposite first and second margins. The source may include horizontally spaced first and second source portions. The first source portion may be adjacent the first margin of the thick oxide portion, and the second source portion may be adjacent the second margin of the thick oxide portion. The thin oxide portion may include horizontally spaced first and second sections on opposite sides of the central section. The first section of the thin oxide portion may be located between the gate and the first source portion, and the second section of the thin oxide portion may be located between the gate and the second source portion.

A well may be positioned adjacent the second end of the volume of semiconductor material. The well may include horizontally spaced first and second well portions that define therebetween a JFET neck region of the drift region. The first well portion may be located between the first source portion and the JFET neck region, and the second well portion may be located between the second source portion and the JFET neck region. The first section of the thin oxide portion may be located between the gate and the first well portion, and the second section of the thin oxide portion may be located between the gate and the second well portion. The thick gate oxide portion and the central section of the thin oxide portion may extend across at least the JFET neck region.

The thickness of the thick gate oxide portion may be approximately ten (10) times greater than the thickness of the thin gate oxide portion.

The material forming the thick oxide portion may have a dielectric constant of less than three or approximately equal to three (3).

The operation of forming the source may include forming horizontally spaced first and second source sections, with the source sections being adjacent respective horizontally opposite first and second margins of the thick oxide portion. A well may be formed adjacent the second end of the volume of semiconductor material. The operation of forming the well may include forming horizontally spaced first and second well sections which define therebetween a JFET neck region of the drift region. The operation of forming the gate oxide may include separating the thin oxide portion into horizontally spaced first and second sections, positioning the first section of the thin oxide portion between the gate and the first source and well portions, and positioning the second section of the thin oxide portion between the gate and the second source and well portion. The operation of positioning the thick oxide portion between the gate and the drift region may include positioning the thick gate oxide portion across at least the JFET neck region.

The operation of forming the gate oxide may include locating a third central section of the thin oxide portion between the thick oxide portion and the JFET neck region.

The operation of forming the gate oxide may include forming the thin oxide portion of a material selected from the group consisting of silicon dioxide, aluminum dioxide, hafnium dioxide, silicon nitride, and combinations thereof. The operation of forming the gate oxide may include forming the thick oxide portion of a material selected from the group consisting of porous silicon dioxide, fluorine-doped silicon oxide, carbon-doped silicon oxide, organosilicate glass, silsesquioxane, and combinations thereof.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current technology will be apparent from the following detailed description of the various examples and the accompanying drawing figures.

### BRIEF DESCRIPTION OF DRAWINGS

Various examples of the current technology are described in detail below with reference to the attached drawing figures, wherein:

FIG. 1 is a schematic cross-sectional view of a field effect transistor, constructed in accordance with a first example of the current technology and including a thick gate oxide portion with a low dielectric constant to provide reduced switching times;

FIG. 2 is a schematic cross-sectional view of a second example of the field effect transistor including the thick gate oxide with the low dielectric constant as well as a central section of a thin gate oxide portion in contact with the gate oxide;

FIGS. 3A, 3B, 3C, 3D, and 3E illustrate portions of the field effect transistor during a plurality of operations of a method for fabricating the field effect transistor having a thick gate oxide portion with a low dielectric constant;

FIG. 4 includes a listing of at least a portion of the operations of the method for fabricating the field effect transistor having the thick gate oxide with the low dielectric constant;

FIGS. 5A, 5B, 5C, 5D, and 5E illustrate portions of the field effect transistor during a plurality of operations of a method for fabricating the field effect transistor having a thick gate oxide portion with a low dielectric constant, as well as having a central section of a thin oxide portion gate in contact with and interposed between the thick oxide portion and the drift region; and

FIG. 6 includes a listing of at least a portion of the operations of the method for fabricating the field effect transistor having the thick gate oxide layer with the low dielectric constant as well as the thin oxide layer in contact with the thick gate oxide layer.

The drawing figures do not limit the current technology to the specific examples disclosed and described herein. The drawings are not necessarily to scale, emphasis instead being placed upon clearly illustrating the principles of the technology.

### DETAILED DESCRIPTION

The following detailed description of the technology references the accompanying drawings that illustrate specific examples in which the technology can be practiced. The various examples are intended to describe aspects of the technology in sufficient detail to enable those skilled in the art to practice the technology. Other examples can be utilized and changes can be made without departing from the scope of the current technology. The following detailed description is, therefore, not to be taken in a limiting sense. The scope of the current technology is defined only by the appended claims, along with the full scope of equivalents to which such claims are entitled. In addition, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

In the following description, the word “voltage” may be used to describe electric voltage, the word “current” may be used to describe electric current, and the word “power” may be used to describe electric power. Relational and/or directional terms, such as “above,” “below,” “up,” “upper,” “upward,” “down,” “lower,” “downward,” “top,” “bottom,” “outer,” “inner,” “left,” “right,” etc., along with orientation terms, such as “horizontal” and “vertical”, may be used throughout this description. These terms retain their commonly accepted definitions and are used with reference to embodiments of the technology and the positions, directions, and orientations thereof shown in the accompanying figures. However, examples of the technology in practice may be positioned and oriented in other ways or move in other directions. Therefore, the terms do not limit the scope of the current technology.

Field-effect transistors (FETs), such as metal oxide semiconductor FETs (MOSFETs) and junction FETs (JFETs), are semiconductor material devices that include three terminals, a gate, a drain, and a source, wherein a voltage is applied to one of the terminals, i.e., the gate, in order to control current flow between the other two terminals, i.e., the drain and the source. Silicon (Si) is typically used as the semiconductor material, although in high voltage applications, silicon carbide (SiC) is utilized—resulting in a SiC power FET. The structure of the SiC power FET, described in more detail below, includes a gate positioned over a drift region with a gate oxide positioned therebetween. The gate and the drift region are formed from electrically conductive, or at least semiconductive, material(s), and the gate oxide is formed from electrically insulating, or dielectric, material(s). The structure of the listed components being formed from the listed material(s) creates a capacitor. Applying voltage to the gate at a first voltage level allows for increased current flow in the drift region, which switches the SiC power FET on. Applying voltage to the gate at a second voltage level results in decreased current flow in the drift region, which switches the SiC power FET off. Because the structural combination of the gate, the gate oxide, and the drift region forms a capacitor, a period of time to switch the SiC power FET on (which may be considered charging the capacitor) and a corresponding period of time to switch the SiC power FET off (which may be considered discharging the capacitor) vary according to a value of a capacitance of the structural combination. In a simplified form, an equation to determine the switch on time and the corresponding switch off time of the SiC power FET is given as: t=C×R, wherein t is the time (in seconds), C is the capacitance of the structural combination, and R is a resistance of circuitry used to apply voltage to the gate. Thus, the switching time of the SiC power FET may be reduced by reducing the capacitance of the gate, the gate oxide, and the drift region.

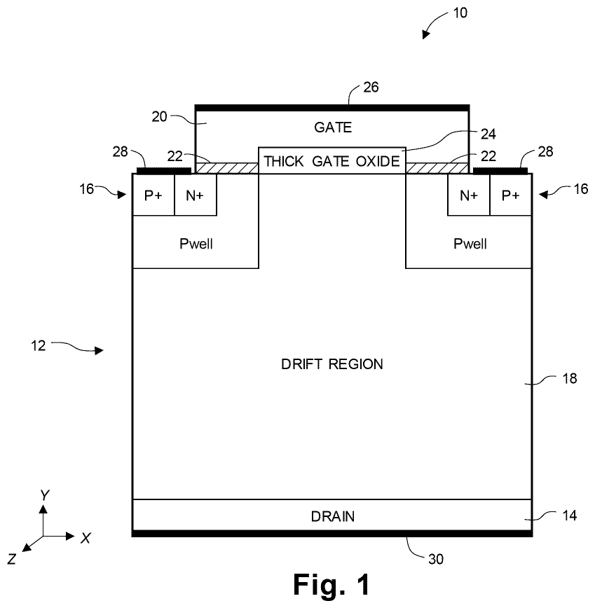

Referring to FIG. 1, an improved SiC power FET 10 is shown. Examples of the FET 10 shown in the figures include a MOSFET. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. The FET 10 broadly comprises a volume of semiconductor material 12, a drain 14, a source 16, a drift region 18, a gate 20, a gate oxide. In the example depicted in FIG. 1, the gate oxide includes a peripheral thin gate oxide portion 22 and a thick gate oxide portion 24.

It will also be appreciated that the sides of the illustrated volume of semiconductor material 12 are defined herein merely to represent a portion of semiconductor material relative to the illustrated FET 10. In practice, the volume of semiconductor material 12 may extend laterally beyond the bounds illustrated in the drawings (leftward and rightward along an X dimension when viewing FIG. 1) to present additional semiconductor material in which additional devices may be provided. Such additional devices may be MOSFETs (which may be similarly or alternatively constructed to the FET 10) or may be entirely different devices providing different operations or functions than the FET 10.

The volume of semiconductor material 12 presents a first (or bottom) end, a second (or top) end opposite and vertically spaced (along a Y dimension) from the first end, a first (or left) side, and a second (or right) side opposite and laterally spaced (along the X dimension) from the first side. In addition, the volume of semiconductor material 12 may have a front end and a back end opposite and axially spaced (along a Z dimension) from the front end. The volume of semiconductor material 12 may be constructed from or include an N-epitaxial (epi) semiconductor material. In the illustrated example, the first end of the volume of semiconductor material is planar with the FET components (including the source 16, gate 20, thin gate oxide portion 22, and thick gate oxide portion) being located at and along the first end. However, according to some aspects of the example FET, a trench (not shown) may extend from the first end and one or more of the FET components may be located within the trench. The volume of semiconductor material 12 may comprise SiC.

The drain 14 is a layer of doped material spaced from the source 16. In the illustrated example, the drain 14 is located at the first end of the volume of semiconductor material 12 and may be formed from or include an N+material, although certain examples contemplate the use drain being located elsewhere, including on the same (second) end of the volume of semiconductor material 12 as the source 16.

The source 16 is positioned at the second end of the volume of semiconductor material 12. In the illustrated FET 10, the source 16 may generally be split into two (2) sections (or portions) positioned adjacent the left and right sides of an upper region of the volume of semiconductor material 12. A left side section is positioned on the left side of the volume of semiconductor material 12 and includes an N+material, and a right side section is positioned on the right side of the volume of semiconductor material 12 and includes an N+material. Left and right wells are provided adjacent the respective left and right source sections. The left and right wells may be shorted such that they may be considered first and second portions of a common well. A body contact (or doped region) is located at the second end on the opposite side of the respective source section from the well. The body contact may be formed of P+material and the well may be formed of P material. Each well extends from the first end of the volume of semiconductor material 12 at a location inwardly (closer to the center of the FET 10) from the respective source 16 section and also in part underlies the respective source 16 section and body contact. In the illustrated example, the FET 10 side structures (each comprising the corresponding source section, well, and doped region) are mirror images of one another, although side structures having different configurations are within the ambit of certain aspects of the example FET 10.

The drift region 18 is positioned between the source 16 and drain 14 and, in the illustrated example, extends to the second end of the volume of semiconductor material 12 to the drain 14. The drift region 18 provides a pathway for one or more channel(s) through which the majority charge carriers move and the electric current flows between the source and the drain. The drift region 18 may be formed from N-doped epi material. The innermost margins of the well portions define therebetween a JFET next region of the drift region 18, with the JFET neck region extending from the second end of the volume of semiconductor material 12. Each of the well portions is located between the respective source section and the JFET neck region.

The gate 20 is positioned above the second end of the volume of semiconductor material 12. The gate 20 includes a top wall, a left side wall, and a right side wall. The left side wall extends downward from a left edge of the top wall, and the right side wall extends downward from a right edge of the top wall. The gate 20 is formed from polysilicon, a metal or alloy of metals, or other suitable material.

The peripheral thin gate oxide portion 22 of the gate oxide includes a first section positioned between the gate 20 and the left section of the source 16 and a horizontally (or laterally) spaced-apart second section positioned between the gate 20 and the right section of the source 16. The first and second sections of the peripheral thin gate oxide 22 are each positioned on a respective opposing side of the thick gate oxide 24. The peripheral thin gate oxide portion 22 is formed from silicon dioxide, aluminum dioxide (Al2O3), hafnium dioxide, silicon nitride, combinations thereof, or other suitable insulating or dielectric material. It may also be said that the thin gate oxide portion is formed of a material having a dielectric constant “k” greater than four (4).

The thick gate oxide portion 24 of the gate oxide is positioned between the gate 20 and the second end of the volume of semiconductor material 12 (i.e., the upper edge of the JFET neck region of the drift region 18). The thick oxide portion 24 extends continuously between the first and second sections of the peripheral thin gate oxide portion 22. The thick gate oxide portion 24 presents horizontally spaced first and second margins, with the first section of the source being adjacent the first margin of the thick oxide portion 24, and the second source section being adjacent the second margin of the thick oxide portion 24. As noted above, the innermost margins of the well portions define therebetween the JFET neck region of the drift region 18. In the illustrated example, the thick oxide portion 24 extends only the width of the JFET neck region so the thick oxide portion 24 terminates at (the first and second margins thereof align with) the innermost margins of the well portions. However, according to certain examples, the thick oxide portion may alternatively extend beyond the innermost margins of the well portions, such that the thick oxide portion overlies part of each of the well portions. The thick gate oxide 24 is formed from one or more material(s) that have a low dielectric constant “k” (or “κ” (kappa)), as referenced in the equation for determining a capacitance “C” of a capacitor formed by the gate 20 being spaced apart from the drift region 18, wherein: C=(k×ε0×A)/t. “ε0” is the permittivity of free space, “A” is the area (length×width or X dimension×Y dimension) of the overlap of the gate 20 with the upper edge of the drift region 18, and “t” is a thickness of the thick gate oxide 24. The dielectric constant “k” may have a value of less than or approximately equal to four (4). According to certain examples, the dielectric constant “k” is between approximately three (3) and approximately four (4), and in yet further specific examples the dielectric constant “3” is less than three (3). The thick gate oxide portion 24 is formed from one or more of porous silicon dioxide (SiO2), fluorine-doped silicon oxide (SiOF), carbon-doped silicon oxide (SiCOH), organosilicate glass (OSG), silsesquioxanes (SSQ), and various spin-on organic polymers like polyimide, polynorbornenes, and benzocyclobutene; all of which achieve low dielectric constant values by introducing porosity or specific chemical modifications. In various examples, the thickness of the thick gate oxide 24 may be approximately ten (10) times greater than a thickness of the thin gate oxide portion 22.

The FET 10 additionally comprises a plurality of contacts, or electrodes, which provide electrical contact between various components and bond wires that connect to a package for the FET 10. Specifically, the FET 10 includes a gate contact 26 to provide electrical contact with the gate 20, a source contact 28 to provide electrical contact with the source 16, and a drain contact 30 to provide electrical contact with the drain 14. Each contact is formed from metals or metal alloys.

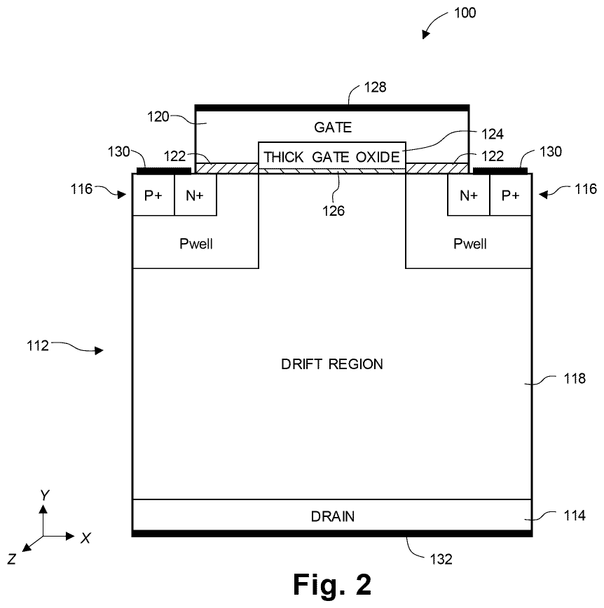

Referring to FIG. 2, a second example of an improved SiC power FET 100 is shown. The FET 100 is substantially similar to the FET 10, except that the FET 100 includes a central section 126 of the thin gate oxide portion 122. The FET 100 broadly comprises a volume of semiconductor material 112, a drain 114, a source 116, a drift region 118, a gate 120, and a gate oxide. In the example depicted in FIG. 2, the gate oxide includes the thin gate oxide portion 122 and a thick gate oxide portion 124. The thin gate oxide portion includes horizontally spaced first and second side sections (each positioned between a respective section of the source 116 and the and the gate 120) and the central section 126. The volume of semiconductor material 112, the drain 114, the source 116, the drift region 118, the gate 120, and the thick gate oxide portion 124 are each substantially similar to, or the same as, the respective like-named components described above for the FET 10. The central oxide section 126 is a thin oxide layer positioned between the thick gate oxide 124 and the drift region 118 and between the first and second (left and right) sections of the thin gate oxide portion 122. The central oxide section 126 extends continuously between the side sections of the thin oxide portion 122, such that the thin oxide portion 122 extends continuously between the left and right sides of the volume of semiconductor material 112. However, according to certain examples, the central oxide section 126 may be segmented or otherwise present discontinuity between the side sections of the thin oxide portion 122. Similar to the side sections of the thin gate oxide portion 122, the central oxide section 126 is formed from silicon dioxide, aluminum dioxide (Al2O3), hafnium dioxide, silicon nitride, or other suitable insulating or dielectric material. According to certain examples, the central section and the side sections of the thin oxide portion may be formed of dissimilar dielectric materials or a pair of the sections (e.g., the side sections) may be formed of one dielectric material and the other section (e.g., the central section) may be formed of a second dielectric material. The central section 126 of the thin oxide portion 122 provides an improved interface between the thick gate oxide 124 and the drift region 118. The central section 126 may have a thickness that ranges from approximately ten (10) to approximately twenty (20) times less than the thickness of the thick gate oxide 124.

The FET 100 additionally comprises a plurality of contacts, or electrodes, which provide electrical contact between various components and bond wires that connect to a package for the FET 100. Specifically, the FET 100 includes a gate contact 128 to provide electrical contact with the gate 120, a source contact 130 to provide electrical contact with the source 116, and a drain contact 132 to provide electrical contact with the drain 114. Each contact is formed from metals or metal alloys.

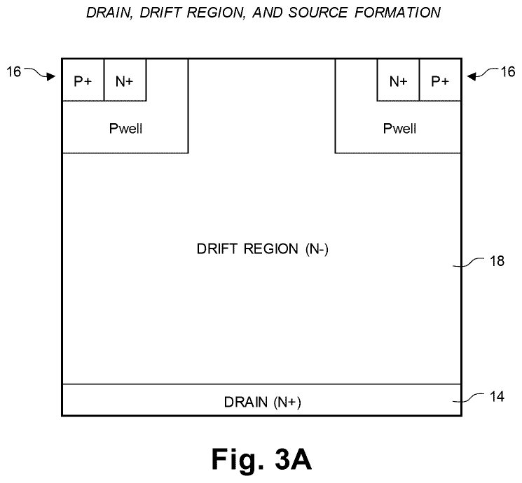

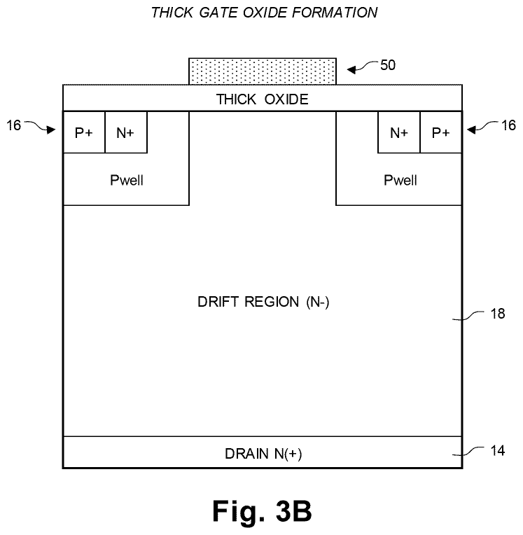

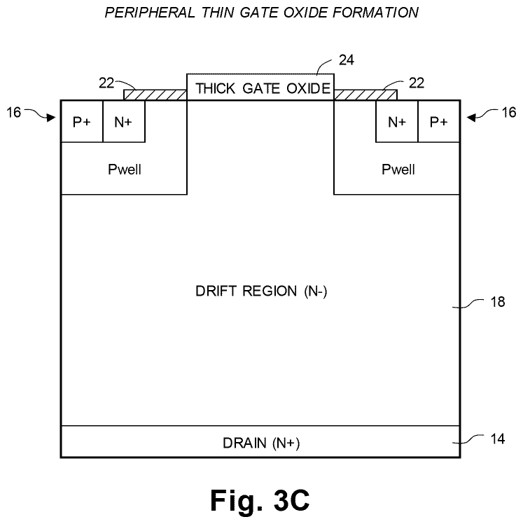

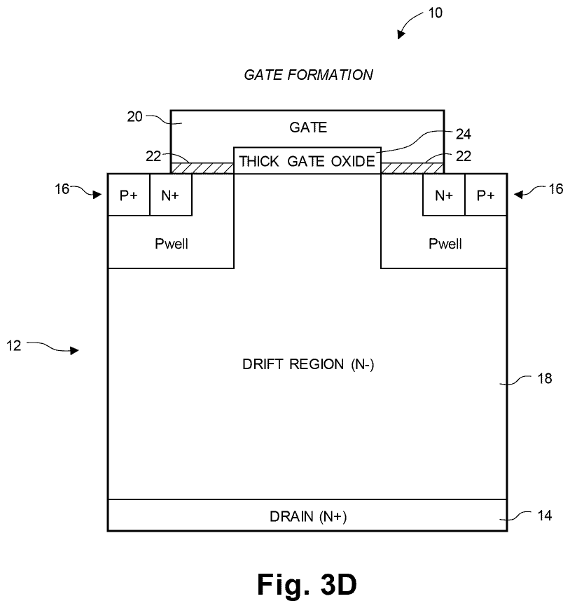

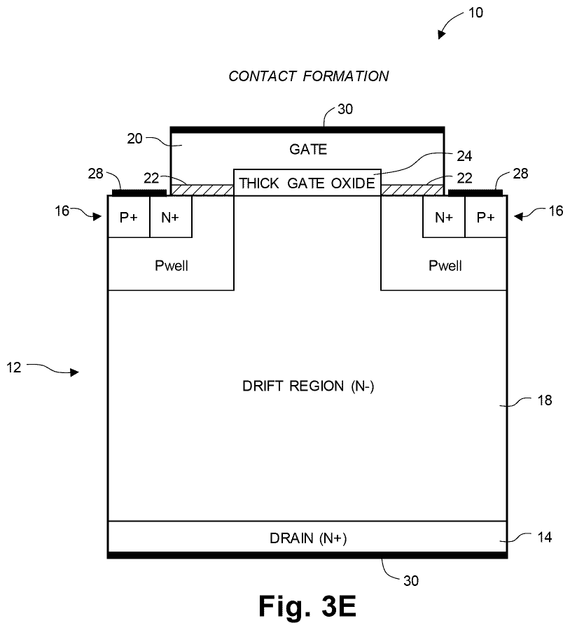

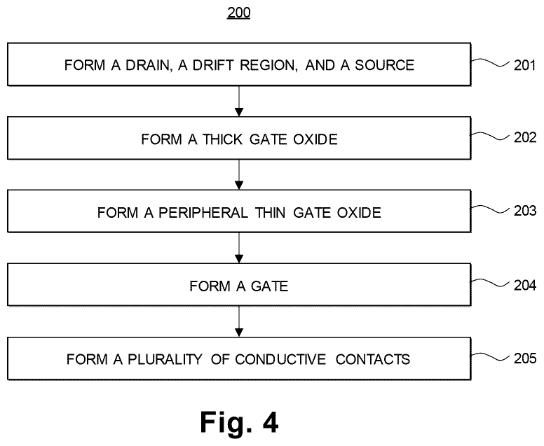

Referring to FIGS. 3A-3E, portions of the FET 10 are shown during various operations of a method 200 for fabricating the FET 10 to include a gate oxide with a reduced dielectric constant. In addition, each operation of the method 200 may be listed in a respective one of a plurality of blocks shown in FIG. 4. Each operation discussed may include numerous sub operations.

Referring to block 201 and FIG. 3A, a drain 14, a drift region 18, and a source 16 are formed. The drain 14 and the drift region 18 may be formed in a stack. The drain 14 may be an N+ substrate, and semiconductor material, including the volume of semiconductor material 12, may be formed utilizing various deposition techniques for epitaxial crystal growth. The semiconductor material may be grown to a height of a top of the drift region 18. The volume of semiconductor material 12 is formed by implanting the semiconductor material with N-material (or the N-doping may be provided as the semiconductor material is epitaxially grown). The source 16 is formed adjacent (or at) the upper end of the volume of semiconductor material 12. In the illustrated example, the source 16 includes a left side section and a right side section. Left and right wells (or well portions) are formed (examples of which are formed from P material), with the left P-well being formed alongside the inner margin of the left side section of the source 16, and the right P-well being formed alongside the inner margin of the right side section of the source 16. The left and right P-wells define the upper portion of the drift region 18, which is commonly referred to as the JFET neck region of the draft region 18. The left and right P-wells may be formed using various implantation techniques. The left side section of the source 16 (which may be an N+ material) and a left side doped region (or body contact which may be a P+ material) may be formed by implantation within the left P-well. The right side section of the source 16 (which may be an N+ material) and a right side doped region (or body contact which may be a P+material) may be formed by implantation within the right P-well.

Referring to block 202 and FIG. 3B, a gate oxide is formed starting with the thick gate oxide portion 24. A thick oxide layer is formed (e.g., deposited, grown, formed by thermal oxidation, etc.) on an upper surface of the volume of semiconductor material 12 including upper portions of the drift region 18, the well, the body contact, and the source 16. The thick oxide layer may be formed of a material having a dielectric constant “k” less than or approximately equal to four (4) and, more preferably, less than three (3). The thick oxide layer may include one or more of porous silicon dioxide (SiO2), fluorine-doped silicon oxide (SiOF), carbon-doped silicon oxide (SiCOH), organosilicate glass (OSG), silsesquioxanes (SSQ), and various spin-on organic polymers like polyimide, polynorbornenes, and benzocyclobutene. A mask 50 including at least first and second openings aligned with the side structures of the FET 10 (the source 16, the well, and the body contact) is positioned over the thick oxide layer. For example, the first opening is aligned with the components (P+ material of the body contact, N+ material of the source 16, and the Pwell) of the left side FET structure, and the second opening is aligned with the components (P+ material of the body contact, N+ material of the source 16, and the Pwell) of the right side FET structure. A solid portion of the mask 50 is aligned with and covers the upper portion of the drift region 18 between the left and right Pwell portions. Etchant is applied to the mask 50, resulting in the thick oxide layer aligned with the first and second openings of the mask 50 being removed—thus forming the thick gate oxide portion 24 (shown in FIG. 3C).

Referring to block 203 and FIG. 3C, the thin gate oxide portion 22 is formed. The thin gate oxide portion 22 includes a first section positioned on the left side of the thick gate oxide 24 and a second section positioned on the right side of the thick gate oxide 24. The peripheral thin gate oxide portion 22 may be formed by positioning a mask (not shown in the figures) over the upper surface of the volume of semiconductor material 12. The mask may include at least first and second openings aligned with portions of the FET side structures. For example, the first opening may be aligned with a portion of the N+ material and a portion of the Pwell of the left side section of the source 16. The second opening may be aligned with a portion of the N+ material and a portion of the Pwell of the right side section of the source 16. Solid sections of the mask may be aligned with and cover the thick gate oxide portion 24 and the body contacts (P+ doped region) and the remaining portion of each source side section. A thin oxide layer may be formed by thermal oxidation of top areas of the volume of semiconductor material 12 exposed by the openings in the mask, which forms the peripheral thin gate oxide portion 22. The thin oxide layer may be formed of a material having a dielectric constant “k” greater than four (4). The thin oxide layer may include silicon dioxide, aluminum dioxide (Al2O3), hafnium dioxide, silicon nitride, combinations thereof, or other suitable insulating or dielectric material.

Referring to block 204 and FIG. 3D, a gate 20 is formed. The gate 20 is formed by depositing polysilicon, or other suitable semiconductor or metallic material, onto the gate oxide (which includes the thin gate oxide portion 22 and the thick gate oxide portion 24). Typically, the polysilicon is deposited on the entire upper surface of the volume of semiconductor material 12 (a so-called “full coat”). Then, using a mask to cover the region of the gate 20, the remainder of the polysilicon is etched.

Referring to block 205 and FIG. 3E, a plurality of conductive contacts, or electrodes, are formed, with each contact providing electrical connection between various components and bond wires that connect to a package for the FET 10. Specifically, a gate contact 26 is formed on the gate 20, a source contact 28 is formed on the source 16, and a drain contact 30 is formed on the drain 14. Each contact is formed from metals or metal alloys may be formed using various metal deposition techniques.

Additional processing may be performed as desired.

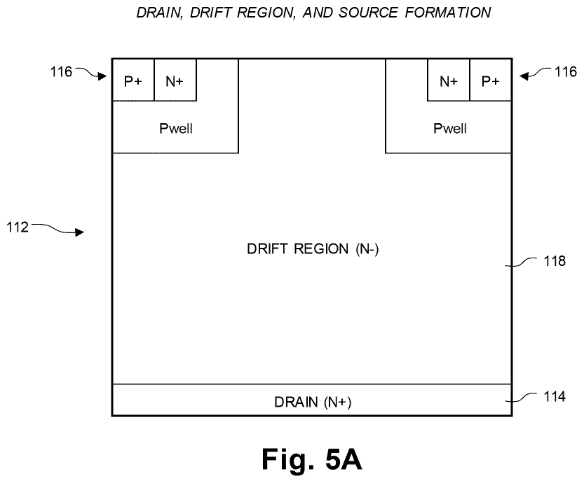

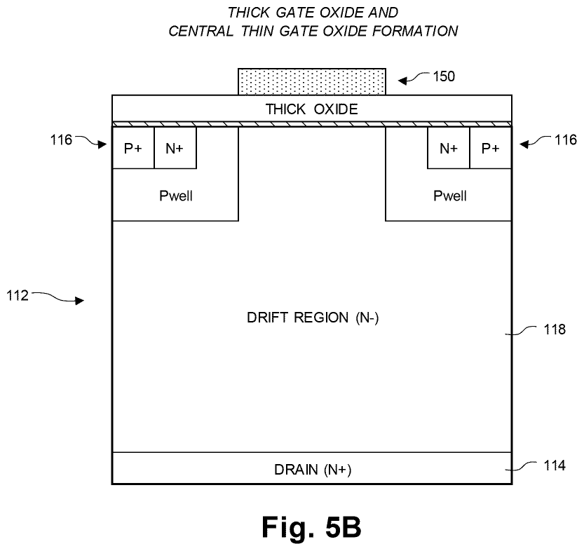

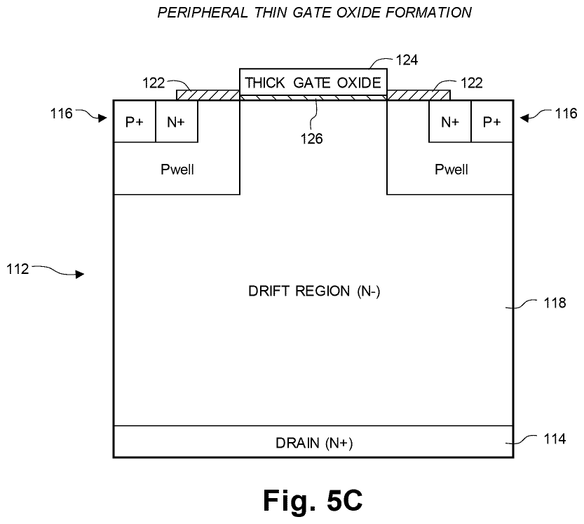

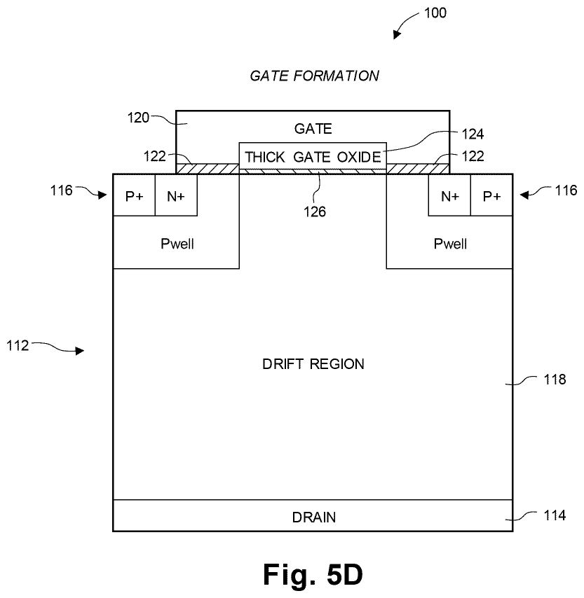

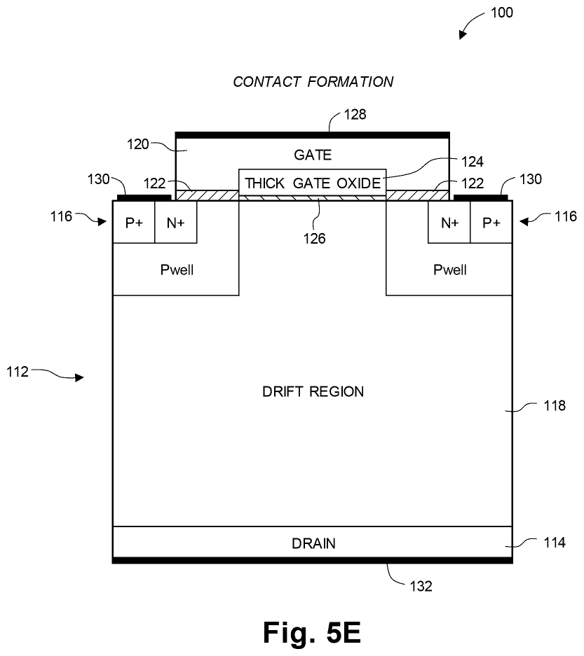

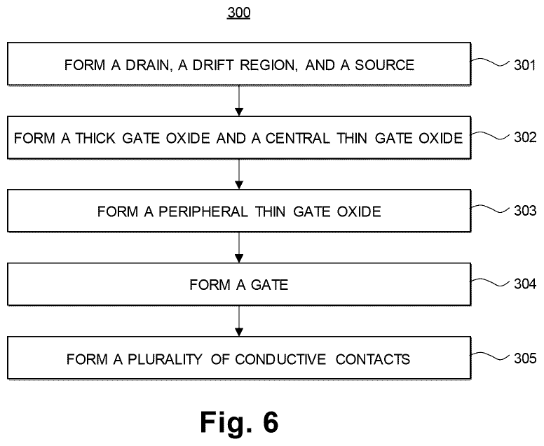

Referring to FIGS. 5A-5E, portions of the FET 100 are shown during various operations of a method 300 for fabricating the FET 100 to include a gate oxide with a reduced dielectric constant. In addition, each operation of the method 300 may be listed in a respective one of a plurality of blocks shown in FIG. 6. Each operation discussed may include numerous sub operations.

Referring to block 301 and FIG. 5A, a drain 114, a drift region 118, and a source 116 are formed. The drain 114 and the drift region 118 may be formed in a stack. The drain 114 may be an N+ substrate, and semiconductor material, including the volume of semiconductor materials 112, may be formed utilizing various deposition techniques for epitaxial crystal growth. The semiconductor material may be grown to a height of a top of the drift region 118. The volume of semiconductor material 112 is formed by implanting the semiconductor material with N-material (or the N-doping may be provided as the semiconductor material is epitaxially grown). The source 116 is formed adjacent (or at) the upper end of the volume of semiconductor material 112. In the illustrated example, the source 116 includes a left side section and a right side section. Left and right wells (or well portions) are formed (examples of which are formed from P material), with the left P-well being formed alongside the inner margin of the left side section of the source 116, and the right P-well being formed alongside the inner margin of the left side section of the source 116. The left and right P-wells may be formed using various implantation techniques. The left side section of the source 116 (which may be an N+ material) and a left side doped region (or body contact which may be a P+ material) may be formed by implantation within the left P-well. The right side section of the source 116 (which may be an N+ material) and a right side doped region (or body contact which may be a P+ material) may be formed by implantation within the right P-well.

Referring to block 302 and FIG. 5B, a gate oxide is formed starting with a thick gate oxide portion 124 and a central section 126 of the thin oxide portion. A thin oxide layer may be formed (e.g., deposited, grown, formed by thermal oxidation, etc.) on an upper surface of the volume of semiconductor material 112 including upper portions of the drift region 118, the well, the body contact, and the source 116. The thin oxide layer may be formed of a material having a dielectric constant “k” greater than four (4). The thin oxide layer may include silicon dioxide, aluminum dioxide (Al2O3), hafnium dioxide, silicon nitride, or other suitable insulating or dielectric material. A thick oxide layer may be deposited on an upper surface of the thin oxide layer. The thick oxide layer may be formed of a material having a dielectric constant “k” less than or approximately equal to four (4) and, more preferably, less than three (3). The thick oxide layer may include porous silicon dioxide (SiO2), fluorine-doped silicon oxide (SiOF), carbon-doped silicon oxide (SiCOH), organosilicate glass (OSG), silsesquioxanes (SSQ), and various spin-on organic polymers like polyimide, polynorbornenes, and benzocyclobutene. A mask 150 including at least first and second openings aligned with the side structures of the FET 100 (the source 116, the well, and the body contact) is positioned over the thick oxide layer. For example, the first opening is aligned with the components (P+ material of the body contact, N+ material of the source 116, and the Pwell) of the left side structure of the FET 100, and the second opening is aligned with the components (P+ material of the body contact, N+ material of the source 116, and the Pwell) of the right side structure of the FET 100. A solid portion of the mask 150 is aligned with and covers the upper portion of the drift region 118 between the left and right Pwell portions. Etchant is applied to the mask 150, resulting in the thick and thin oxide layers aligned with the first and second openings of the mask 150 being removed—thus forming the thick gate oxide 124 and the central oxide section 126 of the thin oxide portion 122 (shown in FIG. 5C). According to certain alternative examples, only the thick oxide layer aligned with the first and second openings of the mask 150 may be removed (e.g., by limiting the depth of the etching process) such that only the thin oxide layer remains, thereby forming the side sections of the thin oxide portion 122 and eliminating the need for step 303 (described immediately below).

Referring to block 303 and FIG. 5C, formation of the gate oxide includes creating a pair of side sections of the thin gate oxide portion 122. In addition to the central section 126, the thin gate oxide portion 122 includes a first section positioned on the left side of the thick gate oxide 124 and a second section positioned on the right side of the thick gate oxide 124. The side sections of the thin oxide portion 122 may be formed by positioning a mask (not shown in the figures) over the upper surface of the volume of semiconductor material 112. The mask may include at least first and second openings aligned with portions of the FET side structures. For example, the first opening may be aligned with a portion of the N+ material and a portion of the Pwell of the left side section of the source 116. The second opening may be aligned with a portion of the N+ material and a portion of the Pwell of the right side section of the source 116. Solid sections of the mask may be aligned with and cover the thick gate oxide portion 124 and the body contacts (P+ doped region) and the remaining portion of each source side section. A thin oxide layer may be formed by thermal oxidation of top areas of the volume of semiconductor material 112 exposed by the openings in the mask, which forms the side sections of the thin gate oxide portion 122. The thin oxide layer may be formed of a material having a dielectric constant “k” greater than four (4). The thin oxide layer may include silicon dioxide, aluminum dioxide (Al2O3), hafnium dioxide, silicon nitride, combinations thereof, or other suitable insulating or dielectric material.

Referring to block 304 and FIG. 5D, a gate 120 is formed. The gate 120 is formed by depositing polysilicon, or other suitable semiconductor or metallic material, onto the gate oxide (which includes the side sections of the thin gate oxide portion 122 and the thick gate oxide portion 124). Typically, the polysilicon is deposited on the entire upper surface of the volume of semiconductor material 112 (a so-called “full coat”). Then, using a mask to cover the region of the gate 120, the remainder of the polysilicon is etched.

Referring to block 305 and FIG. 5E, a plurality of conductive contacts, or electrodes, are formed, with each contact providing electrical connection between various components and bond wires that connect to a package for the FET 100. Specifically, a gate contact 128 is formed on the gate 120, a source contact 130 is formed on the source 116, and a drain contact 132 is formed on the drain 114. Each contact is formed from metals or metal alloys may be formed using various metal deposition techniques.

Additional processing may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well.

Additionally, in general, unless otherwise specified or unless one with ordinary skill in the art would understand otherwise, doping characterized as “++” (e.g., P++) will have a relatively higher concentration of dopants than “+” (e.g., P+) doping, “+” doping will have a relatively higher concentration than “-well” (e.g., P-well) doping, and “-well” doping will have a relatively higher concentration of doping than “−” (e.g., P−) doping. In general, doping concentrations (typically measured in parts-per-cubic-centimeter) for contact implants (e.g., sources, drains, body contacts) may be approximately between 5×10\hat{ }18 and 1×10\hat{ }22; doping concentrations for channel and threshold forming implants (e.g., P-wells) may be approximately between 5×10\hat{ }15 and 5×10\hat{ }17; doping concentrations for shielding implants may be approximately between 5×10\hat{ }17 and 5×10\hat{ }19; and doping concentrations for conductivity improvement implants (e.g., N-doping in the junction field-effect transistor neck region of a metal oxide semiconductor field-effect transistor) may be approximately between 1×10\hat{ }17 and 1×10\hat{ }19.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Throughout this specification, references to “one example,” “an example,” or “examples” mean that the feature or features being referred to are included in at least one example of the technology. Separate references to “one example,” “an example,” or “examples” in this description do not necessarily refer to the same example and are also not mutually exclusive unless so stated or except as will be readily apparent to those skilled in the art from the description. For example, a feature, structure, act, etc. described in one example may also be included in other examples, but is not necessarily included. Thus, the current technology can include a variety of combinations, integrations, or both, of the examples described herein.

Although the present application sets forth a detailed description of numerous different examples, it should be understood that the legal scope of the description is defined by the words of the claims set forth at the end of this patent and equivalents. The detailed description is to be construed as illustrative only and does not describe each possible example since describing each possible example would be impractical. Numerous alternative examples may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the examples illustrated in the attached drawing figures, it is noted that equivalents may be employed and substitutions made herein without departing from the scope of the technology as recited in the claims.

Having thus described various examples of the technology, what is claimed as new and desired to be protected by Letters Patent includes the following:

1. A field effect transistor (FET) comprising:
a volume of semiconductor material including vertically spaced first and second ends;
a source positioned adjacent the second end of the volume of semiconductor material;
a drain spaced apart from the source;
a drift region defined by the volume of semiconductor material positioned between the source and the drain;
a gate positioned adjacent the second end of the volume of semiconductor material; and
a gate oxide including a thin oxide portion and a thick oxide portion that is relatively thicker than the thin oxide portion,
the thin oxide portion being located between the gate and the source,
the thick oxide portion being located between the gate and the drift region,
the thick oxide portion being formed of a material having a dielectric constant of less than or approximately equal to four (4).

2. The FET of claim 1,
the thick oxide portion presenting horizontally opposite first and second margins,
the source including horizontally spaced first and second source portions,
the first source portion being adjacent the first margin of the thick oxide portion, and the second source portion being adjacent the second margin of the thick oxide portion,
the thin oxide portion including horizontally spaced first and second sections,
the first section of the thin oxide portion being located between the gate and the first source portion, and the second section of the thin oxide portion being located between the gate and the second source portion.

3. The FET of claim 2, comprising:
a well positioned adjacent the second end of the volume of semiconductor material,
the well including horizontally spaced first and second well portions that define therebetween a JFET neck region of the drift region,
the first well portion being located between the first source portion and the JFET neck region, and the second well portion being located between the second source portion and the JFET neck region,
the first section of the thin oxide portion being located between the gate and the first well portion, and the second section of the thin oxide portion being located between the gate and the second well portion,
the thick gate oxide portion extending across at least the JFET neck region.

4. The FET of claim 3,
the thin oxide portion including a third central section located between the first and second sections of the thin oxide portion,
the central section of the thin oxide portion being located between the thick oxide portion and the JFET neck region.

5. The FET of claim 4,
each of the first and second well portions presenting an innermost margin located at the JFET neck region,
the first margin of the thick oxide portion being adjacent the innermost margin of the first well portion,
the second margin of the thick oxide portion being adjacent the innermost margin of the second well portion,
the central section of the thin oxide portion extending between the innermost margins of the first and second well portions.

6. The FET of claim 3,
the first well portion in part underlying the first source portion, and the second well portion in part underlying the second source portion.

7. The FET of claim 3,
the second end of the volume of semiconductor material being planar,
the source, well, gate, and gate oxide being located at the second end of the volume of semiconductor material, such that the FET is a planar MOSFET.

8. The FET of claim 1, comprising:
a well positioned adjacent the second end of the volume of semiconductor material,
the well including horizontally spaced first and second well portions that define therebetween a JFET neck region of the drift region,
the thick gate oxide portion extending across at least the JFET neck region.

9. The FET of claim 1,
the thin gate oxide portion including material selected from the group consisting of silicon dioxide, aluminum dioxide, hafnium dioxide, silicon nitride, and combinations thereof.

10. The FET of claim 1,
the thick gate oxide portion including material selected from the group consisting of porous silicon dioxide, fluorine-doped silicon oxide, carbon-doped silicon oxide, organosilicate glass, silsesquioxane, and combinations thereof.

11. The FET of claim 1,
each of the thin and thick gate oxide portions having a respective vertical thickness,
the thickness of the thick gate oxide portion being approximately ten (10) times greater than the thickness of the thin gate oxide portion.

12. The FET of claim 1,
the material forming the thick oxide portion having a dielectric constant of less than three (3).

13. A field effect transistor (FET) comprising:
a volume of semiconductor material including vertically spaced first and second ends;
a source positioned adjacent the second end of the volume of semiconductor material;
a drain spaced apart from the source;
a drift region defined by the volume of semiconductor material positioned between the source and the drain;
a gate positioned adjacent the second end of the volume of semiconductor material; and
a gate oxide including a thin oxide portion and a thick oxide portion that is relatively thicker than the thin oxide portion,
the thick oxide portion being located between the gate and the drift region,
the thick oxide portion being formed of a material having a dielectric constant of less than or approximately equal to four (4),
the thin oxide portion including a central section located between the thick oxide portion and the drift region.

14. The FET of claim 13,
the thick oxide portion presenting horizontally opposite first and second margins,
the source including horizontally spaced first and second source portions,
the first source portion being adjacent the first margin of the thick oxide portion, and the second source portion being adjacent the second margin of the thick oxide portion,
the thin oxide portion including horizontally spaced first and second sections on opposite sides of the central section,
the first section of the thin oxide portion being located between the gate and the first source portion, and the second section of the thin oxide portion being located between the gate and the second source portion.

15. The FET of claim 14, comprising:
a well positioned adjacent the second end of the volume of semiconductor material,
the well including horizontally spaced first and second well portions that define therebetween a JFET neck region of the drift region,
the first well portion being located between the first source portion and the JFET neck region, and the second well portion being located between the second source portion and the JFET neck region,
the first section of the thin oxide portion being located between the gate and the first well portion, and the second section of the thin oxide portion being located between the gate and the second well portion,
the thick gate oxide portion and the central section of the thin oxide portion extending across at least the JFET neck region.

16. The FET of claim 13,
the thin gate oxide portion including material selected from the group consisting of silicon dioxide, aluminum dioxide, hafnium dioxide, silicon nitride, and combinations thereof,
the thick gate oxide portion including material selected from the group consisting of porous silicon dioxide, fluorine-doped silicon oxide, carbon-doped silicon oxide, organosilicate glass, silsesquioxane, and combinations thereof.

17. A method of fabricating a field effect transistor (FET), the method comprising:
providing a volume of semiconductor material to present vertically spaced first and second ends;
forming a source adjacent the second end of the volume of semiconductor material;
forming a drain spaced from the source, such that a drift region defined by the volume of semiconductor material is positioned between the source and the drain;
forming a gate oxide adjacent the second end of the volume of semiconductor material to include a thin oxide portion and a thick oxide portion that is relatively thicker than the thin oxide portion; and
forming a gate adjacent the second end of the volume of semiconductor material,
the operation of forming the gate oxide including positioning the thin oxide portion between the gate and the source,
the operation of forming the gate oxide including positioning the thick oxide portion between the gate and the drift region, with the thick oxide portion being formed of a material having a dielectric constant of less than or approximately equal to four (4).

18. The method of fabricating the FET of claim 17,
the operation of forming the source including forming horizontally spaced first and second source sections, with the source sections being adjacent respective horizontally opposite first and second margins of the thick oxide portion; and
forming a well adjacent the second end of the volume of semiconductor material,
the operation of forming the well including forming horizontally spaced first and second well sections which define therebetween a JFET neck region of the drift region,
the operation of the forming the gate oxide including separating the thin oxide portion into horizontally spaced first and second sections, positioning the first section of the thin oxide portion between the gate and the first source and well portions, and positioning the second section of the thin oxide portion between the gate and the second source and well portion,
the operation of positioning the thick oxide portion between the gate and the drift region including positioning the thick gate oxide portion across at least the JFET neck region.

19. The method of fabricating the FET of claim 18, comprising:
the operation of forming the gate oxide including locating a third central section of the thin oxide portion between the thick oxide portion and the JFET neck region.

20. The method of fabricating the FET of claim 17,
the operation of forming the gate oxide including forming the thin oxide portion of a material selected from the group consisting of silicon dioxide, aluminum dioxide, hafnium dioxide, silicon nitride, and combinations thereof
the operation of forming the gate oxide including forming the thick oxide portion of a material selected from the group consisting of porous silicon dioxide, fluorine-doped silicon oxide, carbon-doped silicon oxide, organosilicate glass, silsesquioxane, and combinations thereof.
